(19) United States
(12) Patent Application Publication
(10) Pub. No.: US 2009/0188548 A1
(43) Pub. Date: Jul. 30, 2009

(54) METHOD FOR PRODUCING A LAYER CONTAINING INORGANIC SEMICONDUCTOR PARTICLES, AND COMPONENTS COMPRISING SAID LAYER

(75) Inventors: Monika Sofie Piber, Anger (AT); Gregor Trimmel, Graz (AT); Franz Stelzer, Graz (AT); Thomas Rath, Graz (AT); Albert K. Plessing, Brunn (AT); Dieter Meissner, Wels (AT)

Correspondence Address: YOUNG & THOMPSON, 209 Madison Street, Suite 500, ALEXANDRIA, VA, 22314, US

(73) Assignee: ISOVOLTA AG, Wiener Neudorf (AT)

(21) Appl. No.: 12/306,120

(22) PCT Filed: Jun. 18, 2007
(86) PCT No.: PCT/AT2007/000294

§ 371 Date: Mar. 13, 2009

(30) Foreign Application Priority Data
Jun. 22, 2006 (AT) A1060/2006

(51) Int. Cl. H01L 31/0264; H01B 1/12

(52) U.S. Cl. 136/252; 252/501.1; 257/E31.004

(57) ABSTRACT

The invention relates to a method for producing a layer containing inorganic semiconductor particles. According to the invention, the layer containing inorganic semiconductor particles is formed in situ from metal salts and/or metal compounds and a salt-type or organic reactant within a semiconducting organic matrix. The layers containing inorganic semiconductor particles and produced according to the invention enable a simple and cost-effective production process for photovoltaic elements, such as solar cells or photodetectors.

The invention relates to a process for the production of an inorganic semiconductor-particle-containing layer as well as components that comprise this layer.

A component of the above-mentioned type is known from WO-A1-00/33396, which has inorganic semiconductor particles in colloidally dissolved form.

These components include, for example, solar cells, which convert sunlight into electrical energy. In this case, the energy production is carried out by a solar cell system, which consists of a hybrid layer. Such hybrid solar cells, also named nanocomposite solar cells, consist of inorganic semiconductors, such as, for example, CdSe^{[1-4]}, Cds^{[5]}, CdTe^{[6]}, ZnO^{[7]}, TiO₂^{[8, 9]}, CuInS₂^{[10-13]} or CuInSe₂^{[14]} or fullerenes^{[15-20]} and an electroactive polymer.

The production of the inorganic semiconductor particles for such solar cells can be carried out by using the most varied methods. The most common methods are the colloidal synthesis with use of a capper and the solvothermal synthesis in the autoclave.

These processes are relatively expensive, however, since the use of a capper is necessary to prevent the undesirable agglomeration of the nanoparticles that are used.

The invention is intended to correct this.

According to the invention, a process of the above-mentioned type is indicated, which is characterized in that the inorganic semiconductor-particle-containing layer is formed in situ from metal salts and/or metal compounds and a salt-like or inorganic reactant within a semiconducting organic matrix.

Other advantageous embodiments of the process according to the invention are disclosed according to subclaims.

The invention also relates to components comprising the inorganic semiconductor-particle-containing layer produced according to the invention. In an advantageous way, these components according to the invention are solar cells, in particular hybrid solar cells. The components according to the invention, which comprise the inorganic semiconductor-particle-containing layer that is produced according to the invention, include additional photodetectors.

If a solar cell is to be produced as a component according to this invention, inorganic particles, as starting products, directly within the photoactive layer of the solar cell in situ in a semiconducting organic matrix, consisting of, for example, low-molecular electroactive molecules, semiconducting polymers and/or oligomers, are converted into semiconductors. In comparison to colloidal synthesis, this has the advantage that the colloidal synthesis step and the associated, very expensive working-up steps can be eliminated. As a result, a significantly simpler and more economical production process is made available.

Another essential advantage of this invention lies in the fact that a capper can be eliminated. Cappers consist primarily of organic surfactants, which in most cases are insulators. These insulators impede the dissociation from excitons (electron-hole pairs) at the p/n boundary layer as well as the charge transport for electrodes and thus reduce the degree of efficiency of the solar cells. By the construction of nanocomposite solar cells without an insulating capper, the conductivity of the active layers, in particular the n-conductor, and thus the degree of efficiency can be significantly improved.

For the production of layers for the components according to the invention, the respective inorganic and organic starting compounds are applied as film and then converted into semiconductors.

Another, likewise advantageous production process for the components according to the invention consists in that the semiconducting layers are produced by applying the organic and inorganic starting compounds with simultaneous conversion into semiconductors.

The conversion of the starting compounds into semiconductors within the organic matrix is preferably carried out by thermal treatment of the starting compounds at temperatures of between 50° and at most 400° C. To produce the photoactive semiconductor layers according to the invention, temperatures significantly less than 400° C. are used, since temperatures that are too high can lead to undesirable reactions of the starting compounds or decomposition products. By the production of photoactive semiconductor layers at low temperatures, the use of ITO (indium tin oxide)-coated plastic substrates and thus the production of flexible solar cells is possible.

With targeted selection of the starting compounds, the conversion temperature can also be less than 100° C.

The conversion of the starting compounds into semiconductors can be carried out in the presence of an acid.

The conversion of the starting compounds into semiconductors can likewise be carried out advantageously in the presence of a base.

Analogously to the thermal treatment, photons with an energy of greater than 1 (one) eV for the conversion of the semiconductors can also be used.

The conversion of the layers into semiconductors can take place in inert gas atmosphere or in air.

When applying the semiconductor layers for the production of the components according to the invention, the starting compounds can be present both as dispersions or suspensions, as solution, as paste or as slurry (pasty suspension).

The starting compounds can also be present in complexed form.

With the process for the production of inorganic semiconductor particles according to the invention, metal compounds that react with a salt-like or organic reactant are used.

In the metal compound that is used as a starting compound, this can be a salt-like compound.

In a like manner, the metal compound can be an organometallic compound or an organometallic complex.

The metal compound that is used can have both basic and acidic properties, which makes the conversion into a semiconductor possible at low temperatures, or catalytically influences this conversion.

The production according to the invention also comprises reactions in the presence of an oxidizing or reducing agent.

A high current yield of the components according to the invention in the form of solar cells is achieved in that the inorganic semiconductor materials are particles whose grain size is between 0.5 nm and 500 nm. The size of these particles greatly depends on the concentration ratios of the starting compounds and the polymer matrix.

The inorganic semiconductor particles also comprise nanoparticles. These nanoparticles can have, in particular, properties such as, e.g., impact ionization, which are used in the third generation of the solar cells, see M. A. Green, Third Generation Photovoltaics, Springer Verlag (2003).

Based on quantum-size effects in the inorganic nanoparticles that are produced, the physical properties of the semiconductors can be different from macroscopic analogs.

The inorganic semiconductor material can also, however, be present in the form of agglomerates of particles as well as from a network with or without noticeable grain boundaries. Via the network, charge carriers can flow into the material, for example, in a percolation mechanism.

The term “inorganic semiconductor particles” comprises sulfides, selenides, tellurides, antimonides, phosphides, carbides, nitrides as well as elementary semiconductors. The above-mentioned inorganic semiconductors are defined as all such known semiconductors.

In solar cells, the inorganic semiconductor particles that are obtained can act as both electron donors and electron acceptors.

It is advisable that the production of the inorganic semiconductor particles be carried out in a semiconducting organic matrix.

This semiconducting organic matrix can consist of low-molecular, organic compounds, such as perylenes, phthalocyanines, or derivatives thereof as well as semiconducting polycyclic compounds.

Another, likewise preferred semiconductor matrix can consist of semiconducting oligomers. In this case, for example, these are oligothiophenes, oligophenylenes, oligophenylenevinylenes as well as the derivatives thereof.

In addition, the semiconductor matrix can consist of electroactive polymers. Possible polymers and copolymers that can be used in the components according to the invention, such as solar cells, are, for example, polyphenylenes, polyphenylenevinylenes, polythiophenes, polyanilines, polypyrroles, polyfluorenes as well as derivatives thereof.

The conductivity of the organic semiconductor matrix can be improved by doping.

In the solar cells, the organic semiconductor matrix can act as both an electron donor and an electron acceptor.

The geometry of the components according to the invention in the form of solar cells comprises bulk heterojunction solar cells. “Bulk heterojunction solar cells” are defined as solar cells whose photoactive layer consists of a three-dimensional network of an electron donor and an electron acceptor.

Likewise, the geometry in the solar cells can correspond to that of a gradient solar cell. The term “gradient solar cell” comprises solar cell geometries that have a gradient of the organic or the inorganic semiconductor material.

Likewise, the solar cells according to the invention can contain a layer of the semiconductor matrix or the inorganic semiconductor, which can act as an intermediate layer.

The stoichiometry of the inorganic semiconductor materials produced according to the invention can be varied by variation of the ratio of the metal compound used relative to the respective reactant as well as to other metal compounds in the initial mixture. This variation makes possible the controlled setting of optical, structural as well as electronic properties. This also makes possible the targeted introduction of flaws and doping materials into the semiconductor materials to allow a broader application.

The invention is based on possible embodiments and figures as explained below:

1. Production of copper indium sulfide-polyphenylenevinylene solar cells:

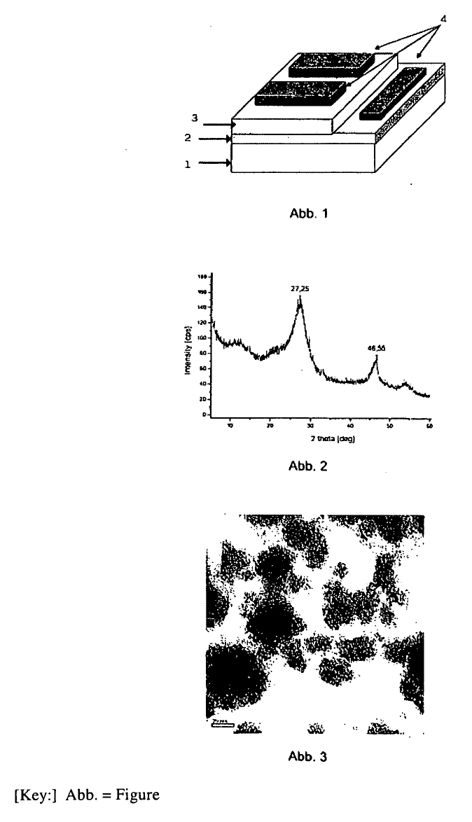

The structure of a solar cell is outlined in FIG. 1. A transparent indium-tin-oxide electrode (ITO electrode) 2, followed by the photovoltaically active composite layer 3, is found in a glass substrate 1. Finally, metal electrodes 4 (calcium/aluminum or aluminum) are vapor-deposited on the composite layer as well as on the transparent electrode. The bonding of the cell is carried out, on the one hand, via the indium tin electrode, and, on the other hand, via a metal electrode on the active layer.

The composite layer was produced by CuI, InCl₃ as well as thioacetamide being dissolved in pyridine (molar ratio of Cu/In/S=0.8/1/2). The solution was mixed with a solution of poly(p-xylene tetrahydrothiophenium chloride) in water/ethanol and dripped onto an ITO substrate. A copper indium sulfide-PPV nanocomposite layer is produced by heating to 200° C. Both the production of nanoparticles and also the production of the conjugated electroactive polymer is carried out in situ.

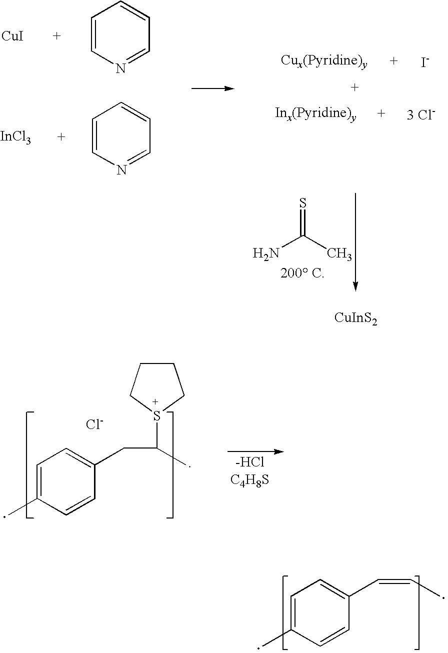

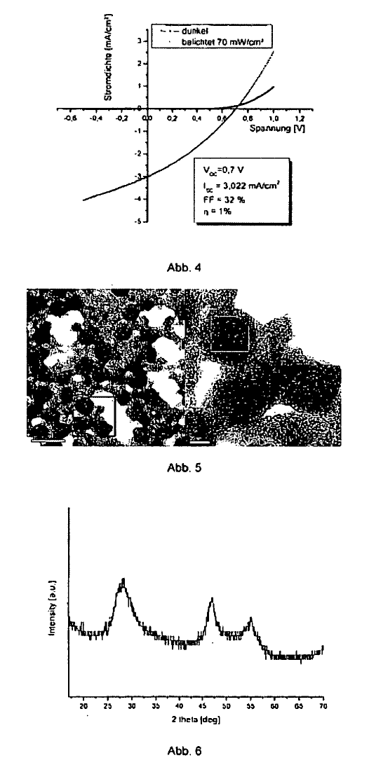

In the x-ray diffractogram according to FIG. 2, the XRD properties of the nanocomposite layers that are produced in this way are shown; the broad peaks at 29°, 44°, and 55° are characteristic of CuInS₂ with a particle size of about 10 nm.

In FIG. 3, the TEM images (transmission electron microscope images) of the photoactive layer are shown. The TEM images show almost spherical particles, which are embedded in the polymer matrix.

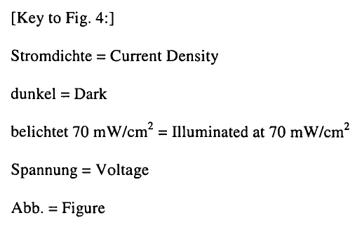

In FIG. 4, current/voltage characteristics are depicted, which show a V_{oc} (open terminal voltage) of 700 mV and an I_{SC} (short-circuit current) of 3.022 mA/cm² at an illumination of 70 mW/cm². The filling factor is 32%, and a degree of efficiency of 1% was achieved.

Analogously to the composite layers produced in Example 1, acetate salts of the above-mentioned elements were used in additional embodiments and solar cells were made. Table 1 shows an overview of the results that are obtained.

TABLE 1

| | 1 | 2 | 3 |
|---|---|---|---|
| S Source | Thioacetamide | Thioacetamide | Thioacetamide |
| Cu Source | CuI | CuAc | CuAc |
| In Source | InCl₃ | InCl₃ | InAc₃ |
| Cu/In/S Ratio | 0.8/1/6 | 0.8/1/6 | 0.8/1/6 |
| VOC [V] | 0.7 | 0.86 | 0.5 |
| ISC [mA/cm²] | 3 | 4.6 | 0.7 |
| FF [%] | 32 | 25 | 25 |
| [symbol] [%] | 1 | 0.7 | 0.1 |
| Electrode Material | Al | Al | Al |

Copper indium disulfide can be produced either as p- or n-conductors. Therefore, the Cu/In/S ratio plays a significant role in the solar cells. Relative to the copper indium sulfide solar cells, several concentration ratios were examined: On the one hand, solar cells were made using Cu/In/S in a 0.8/1/6 ratio and with significant In excess (Cu/In/S 1/5/16) as a starting material, in combination with poly-para-phenylenevinylene. Table 2 shows the results that were obtained. The degree of efficiency significantly increases at this ratio despite a low filling factor by increasing both the V_{oc} and the I_{SC}.

TABLE 2

| | 1 | 2 |
|---|---|---|
| S Source | Thioacetamide | Thioacetamide |
| Cu Source | CuI | CuI |
| In Source | InCl₃ | InCl₃ |
| Cu/In/S Ratio | 0.8/1/6 | 1/5/16 |
| VOC [V] | 0.7 | 0.9 |
| ISC [mA/cm²] | 3 | 5.7 |
| FF [%] | 32 | 26 |
| [symbol] [%] | 1 | 2 |
| Electrode Material | Al | Al |

### EXAMPLE 2

### Zinc Sulfide Copper Indium Disulfide-Polyphenylenevinylene Solar Cells

In the case of these solar cells, the active layers were produced by zinc acetate, CuI, InCl₃ and thioacetamide as well as a poly(p-xylene tetrahydrothiophenium chloride) precursor having been dissolved or complexed in a solvent mixture that consists of pyridine, water and ethanol and a layer having been produced from this solution. By heating, zinc sulfide copper indium sulfide mixed crystals in a PPV polymer matrix were produced.

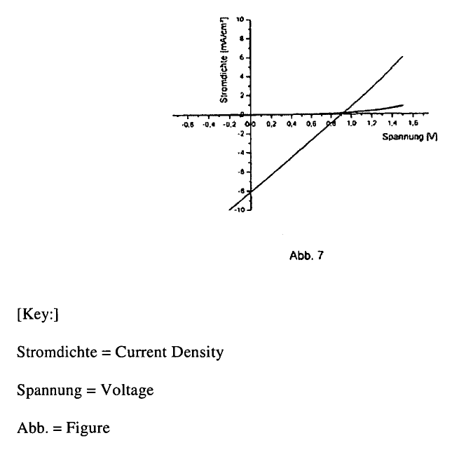

In the TEM images of this zinc sulfide/copper indium sulfide nanocomposite layer, see FIG. 5, it can be seen that uniformly large particles with an approximate diameter of 50-60 nm were produced. No larger particles could be found in the sample. The x-ray diffractogram in FIG. 6, which can be seen as an average over the entire sample, also confirms that only nanometer-size particles were formed, since all peaks are very broad. The current/voltage characteristic of such a solar cell is reproduced in FIG. 7 and shows both a high photoelectric voltage of 900 mV and a photoelectric current of 8 mA/cm².

### EXAMPLE 3

As an alternative to the mentioned PPV precursor, other polymers, such as P3HT (poly-3-hexylthiphene), MEH-PPV (poly[2-methoxy-5-(2′ethyl-hexyl)-1,4-phenylenevinylene]), MDMO-PPV (poly[2-methoxy-5-(3,7-dimethyloctyloxy)-1,4-phenylenevinylene]) or else copolymers can be used. Example 3 shows CuInS₂/MEH-PPV solar cells. The active layers of these solar cells were produced from a solution of CuI/InCl₃/thioacetamide (1/5/16) and MEH/PPV (4/1 CIS/MEH-PPV). Solar cells with MEH-PPV as electroactive polymer achieved a short-circuit current of 4 mA/cm², an open terminal voltage of 0.93 V, and an FF of 25%. The degree of efficiency of these solar cells was 1.3%.

In addition to these accurately described experiments, a number of other studies were performed, in which there could be shown that
1) In addition to the elements Cu, In, and Zn, the elements Ag, Cd, Ga, Al, Pb, Hg, S, Se, and Te can also be used;
2) Besides thioacetamide, the following S compounds can also be used:

elementary sulfur, elementary sulfur with a vulcanization accelerator, thiourea, thiuram, hydrosulfide, metal sulfides, hydrogen sulfides, CS₂, P₂S₅;
3) In addition to the polymers, such as polyphenylene or MEH-PPV, it was also demonstrated that polythiophenes, adder polymers, polyanilines, and also low-molecular organic compounds, such as perylenes, and phthalocyanines, are suitable;
4) In addition to the metal salts, organometallic compounds such as acetates as well as metal thiocarbamide compounds can also be used.

In summary, it can be said that according to this invention, semi-conducting nanoparticles are produced directly on the active layer of the solar cell by thermal decomposition in the presence of organic, electroactive polymers. In comparison to the colloidal synthesis, this brings the advantage that the colloidal synthesis step and the associated, very expensive working-up steps can be eliminated. As a result, a significantly simpler and more economical production process is made available for photovoltaic elements, such as solar cells and photodetectors.
[1] B. Q. Sun, E. Marx, N. C. Greenham, Nano Letters 2003, 3, 961.
[2] W. U. Huynh, J. J. Dittmer, A. P. Alivisatos, Science 2002, 295, 2425.
[3] W. U. Huynh, J. J. Dittmer, P. A. Alivisatos, D. Milliron, Huynh, Wendy U. (DE); Dittmer, Janke J. (DE); Slivisatos, Paul A. (US); Milliron, Delia (US), 2003.
[4] W. U. Huynh, X. Peng, A. P. Alivisatos, Advanced Materials 1999, 11, 923.
[5] N. C. Greenham, X. Peng, A. P. Alivisatos, Physical Review B 1996, 54, 17628.
[6] S. Kumar, T. Nann, Journal of Materials Research 2004, 19, 1990.
[7] D. C. Olson, J. Piris, R. T. Collins, S. E. Shaheen, D. S. Ginley, Thin Solid Films 2006, 496, 26.
[8] C. Y. Kwong, W. C. H. Choy, A. B. Djurisic, P. C. Chui, K. W. Cheng, W. K. Chan, Nanotechnology 2004, 15, 1156.
[9] A. Petrella, M. Tamborra, P. D. Cozzoli, M. L. Curri, M. Stricooli, P. Cosma, G. M. Farinola, F. Babudri, F. Naso, A. Agostiano, Thin Solid Films 2004, 451-452, 64.
[10] E. Arici, H. Hoppe, Schäffler, D. Meissner, M. A. Malik, N. S. Sariciftci, Thin Solid Films 2004, 451-452, 612.
[11] E. Arici, D. Meissner, F. Schaffler, N. S. Sariciftci, International Journal of Photoenergy 2003, 5, 1999.
[12] E. Arici, N. S. Sariciftci, D. Meissner, Encyclopedia of Nanoscience and Nanotechnology 2004.
[13] S. Bereznev, I. Konovalov, A. Opik, J. Kois, E. Mellikov, Solar Energy Materials and Solar Cells 2005, 87, 197.
[14] E. Arici, H. Hoppe, F. Schaffler, D. Meissner, M. A. Malik, N. S. Sariciftci, Applied Physics a-Materials Science & Processing 2004, 79, 59.
[15] C. J. Brabec, N. S. Sariciftci, J. C. Hummelen, Advanced Functional Materials 2001, 11, 15.
[16] C. J. Brabac, S. E. Shaheen, C. Winder, N. S. Sariciftci, P. Denk, Applied Physics Letters 2002, 80, 1288.
[17] D. Meissner, J. Rostalski, Meissner Dieter (DE), Rostalski Joern (DE), Jülich Nuclear Research Facility (DE), 2000.
[18] S. E. Shaheen, C. J. Brabec, N. S. Sariciftci, F. Padinger, T. Fromherz, J. C. Hummelen, Applied Physics Letters 2001, 78, 841.
[19] H. Spanggaard, F. C. Krebs, Solar Energy Materials and Solar Cells 2004, 83, 125.
[20] C. Winder, N. S. Sariciftci, J. Mater. Chem. 2004, 14, 1077.
[21] A. P. Alivisatos, Endeavour 1997, 21, 56.
[22] A. P. Alivisatos, Abstracts of Papers of the American Chemical Society 2004, 227, U1240.
[23] W. U. Huynh, J. J. Dittmer, W. C. Libby, G. L. Whiting, A. P. Alivisatos, Advanced Functional Materials 2003, 13, 73.
[24] W. U. Huynh, J. J. Dittmer, N. Teclemariam, D. J. Milliron, A. P. Alivisatos, K. W. J. Bamham, Physical Review B 2003, 67.
[25] W. U. Huynh, X. G. Peng, A. P. Alivisatos, Advanced Materials 1999, 11, 923.
[26] A. P. Alivisatos, Abstracts of Papers of the American Chemical Society 2004, 227, U1420.
[27] J. Locklin, D. Patton, S. Deng, A. Baba, M. Millan, R. C. Advincula, Chemistry of Materials 2004, new, new.
[28] L. Manna, E. C. Scher, A. P. Alivisatos, Journal of Cluster Science 2002, 13, 521.
[29] S. Bereznev, I. Konovalov, J. Kois, E. Mellikov, A. Opik, Macromolecular Symposia 2004, 212, 287.
[30] S. Bereznev, I. Konovalov, A. Opik, J. Kois, Synthetic Metals 2005, 152, 81.
[31] E. Arici, A. Reuning, N. S. Sariciftci, D. Meissner, in 17^{th} European Photovoltaic Solar Energy Conf., Munich, 2001.
[32] E. Arici, N. S. Sariciftci, D. Meissner, Molecular Crystals and Liquid Crystals 2002, 385, 249.
[33] E. Arici, N. S. Sariciftci, D. Meissner, Advanced Functional Materials 2003, 13, 165.
[34] C. Czekelius, M. Hilgendorff, L. Spanhel, I. Bedja, M. Lerch, G. Müller, U. Bloeck, D.-S. Su, M. Giersig, Advanced Materials 1999, 11, 643.
[35] Y. Zhou, L. Hao, Y. Hu, Y. Zhu, Z. Chen, Chemistry Letters 2001, 30, 136.

1. Process for the production of an inorganic semiconductor-particle-containing layer, characterized in that the inorganic semiconductor-particle-containing layer is formed in situ from metal salts and/or metal compounds and a salt-like or organic reactant within a semiconducting organic matrix.

2. Process according to claim 1, wherein an inorganic semiconductor-containing photoactive layer is formed.

3. Process according to claim 1, wherein inorganic semiconductor particles in an order of magnitude of 0.5 nm to 500 nm are formed in the layer.

4. Process according to claim 1, wherein the inorganic semiconductor particles are formed in the layer by heating the starting components to temperatures of greater than 50° C.

5. Process according to claim 1, wherein the inorganic semiconductor particles are formed in the layer by irradiating the starting components with energies of greater than 1 eV.

6. Process according to claim 1, wherein the inorganic semiconductor particles are sulfides, selenides, or tellurides.

7. Process according to claim 1, wherein the inorganic semiconductor particles are elementary semiconductors.

8. Process according to claim 1, wherein the inorganic semiconductor particles are carbides, phosphides, nitrides, antimonides or arsenides.

9. Process according to claim 1, wherein the inorganic semiconductor particles are oxides.

10. Process according to claim 1, wherein at least one semiconducting polymer that is used is formed as a semiconducting organic matrix.

11. Process according to claim 10, wherein the semiconducting polymer is selected from the group polyphenylenevinylene, polythiophene, polyaniline, polyfluorene, polyphenylene, polypyrrole as well as derivatives thereof.

12. Process according to claim 1, wherein low-molecular organic compounds are used as a semiconducting organic matrix.

13. Process according to claim 12, wherein the low-molecular organic compounds are selected from the group of phthalocyanines as well as perylenes.

14. Component comprising at least one inorganic semiconductor-particle-containing layer that is produced according to a process according to claim 1.

15. Component according to claim 14, wherein the component is a solar cell, preferably a hybrid solar cell.

16. Component according to claim 14, wherein the active element is a photodetector.

17. Process according to claim 2, wherein inorganic semiconductor particles in an order of magnitude of 0.5 nm to 500 nm are formed in the layer.
